(19) United States
(12) Patent Application Publication
(10) Pub. No.: US 2025/0202436 A1
(43) Pub. Date: Jun. 19, 2025

(54) AMPLIFIER CIRCUIT

(71) Applicant: SUMITOMO ELECTRIC INDUSTRIES, LTD., Osaka-shi, Osaka (JP)

(72) Inventor: Hirotaka ASAMI, Osaka-shi (JP)

(73) Assignee: SUMITOMO ELECTRIC INDUSTRIES, LTD., Osaka-shi, Osaka (JP)

(21) Appl. No.: 18/980,607

(22) Filed: Dec. 13, 2024

(30) Foreign Application Priority Data
Dec. 14, 2023 (JP) 2023-211431

(51) Int. Cl. H03F 1/02; H03F 3/21

(52) U.S. Cl. CPC H03F 1/0288; H03F 3/211

(57) ABSTRACT

An amplifier circuit includes a first divider dividing an input signal into first and second signals, a control amplifier outputting a third signal, a second divider dividing the second signal into fourth and fifth signals, a first auxiliary amplifier outputting a sixth signal, a second auxiliary amplifier outputting a seventh signal, and a combiner including first to fourth ends, wherein the amplifier circuit satisfies at least one of conditions a) to c), a) in the combiner, a first division ratio of amplitudes of powers of signals output to the fourth and the third ends is 0.5 dB or more, b) a second division ratio of amplitudes of powers of divided signals in the second divider is 0.5 dB or more, and c) a phase difference between the sixth and the seventh signals is 85° or less or 95° or more.

### CROSS REFERENCE TO RELATED APPLICATIONS

This application claims priority based on Japanese Patent Application No. 2023-211431 filed on Dec. 14, 2023, and the entire contents of the Japanese patent applications are incorporated herein by reference.

### FIELD OF THE INVENTION

A certain aspect of the embodiments is related to an amplifier circuit.

### BACKGROUND OF THE INVENTION

An LMBA (Load Modulated Balanced Amplifier) includes a control amplifier for amplifying one of the signals into which an input signal is divided, and a balance amplifier for amplifying the other signal to which the input signal is divided. The balance amplifier has two auxiliary amplifiers connected in parallel and balanced. It is known to make two auxiliary amplifiers asymmetric. In order to make the two auxiliary amplifiers asymmetric, it is known to make the powers of the two auxiliary amplifiers different from each other, and to make the bias voltages supplied to the two auxiliary amplifiers different from each other as one of the means (for example, Patent Document 1: U.S. Patent Application Publication No. 2022/0255506).

### SUMMARY OF THE INVENTION

An amplifier circuit according to the present disclosure includes a first divider that divides an input signal into a first signal and a second signal; a control amplifier that amplifies the first signal and outputs an amplified signal as a third signal; a second divider that divides the second signal into a fourth signal and a fifth signal having different phases at a center frequency of an operating band; a first auxiliary amplifier that amplifies the fourth signal and outputs an amplified signal as a sixth signal; a second auxiliary amplifier that amplifies the fifth signal and outputs an amplified signal as a seventh signal; and a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, and combines the sixth signal, the seventh signal and the third signal, and outputs a combined signal as the output signal; wherein the amplifier circuit satisfies at least one of following conditions a) to c), a) in the combiner, a first division ratio of amplitudes of powers of signals output to the fourth end and the third end when a signal at the center frequency is input to the first end is 0.5 dB or more; b) a second division ratio of amplitudes of powers of divided signals when a signal at the center frequency is input to the second divider is 0.5 dB or more; and c) a phase difference between the sixth signal input to the first end and the seventh signal input to the second end at the center frequency is 85° or less or 95° or more.

An amplifier circuit according to the present disclosure includes a first divider that divides an input signal into a first signal and a second signal; a control amplifier that operates in class AB or class B, amplifies the first signal, and outputs an amplified signal as a third signal; a second divider that divides the second signal into a fourth signal and a fifth signal having different phases at a center frequency of an operating band; a first auxiliary amplifier that operates in class C, amplifies the fourth signal, and outputs an amplified signal as a sixth signal; a second auxiliary amplifier that operates in class C, amplifies the fifth signal, outputs an amplified signal as a seventh signal, and has a saturation power equal to a saturation power of the first auxiliary amplifier; a bias circuit that supplies a same bias voltage to the first auxiliary amplifier and the second auxiliary amplifier; a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, combines the sixth signal, the seventh signal and the third signal, and outputs a combined signal as the output signal; and a matching circuit that matches an impedance at the center frequency viewed from the matching circuit toward the third end with an impedance at the center frequency viewed from the control amplifier toward the matching circuit; wherein an absolute value of a first impedance at the center frequency viewed from the matching circuit toward the third end when the first auxiliary amplifier and the second auxiliary amplifier operate is 0.9 times or less or 1.1 times or more an absolute value of a second impedance at the center frequency viewed from the matching circuit toward the third end when the first auxiliary amplifier and the second auxiliary amplifier do not operate.

### BRIEF DESCRIPTION OF DRAWINGS

FIG. 1 is a circuit diagram of an amplifier circuit according to a first embodiment.

FIG. 2 is a circuit diagram illustrating an example 1 of a divider in the first embodiment.

FIG. 3 is a circuit diagram illustrating an example 2 of a divider in the first embodiment.

FIG. 4 is a circuit diagram illustrating an example of a combiner in the first embodiment. FIG. 5 is a plan view of a branch line coupler in the first embodiment.

FIG. 6 is a circuit diagram of an amplifier circuit according to a first comparative example.

FIG. 7 is a circuit diagram illustrating a part of an amplifier circuit in a second comparative example and a first embodiment.

FIG. 8 is a circuit diagram illustrating a part of an amplifier circuit in the second comparative example.

FIG. 9 is a Smith chart illustrating an impedance Z1 in the first and the second comparative examples and the first embodiment.

FIG. 10 is a diagram illustrating a drain efficiency with respect to an output power in the first and the second comparative examples and the first embodiment.

FIG. 11 is a circuit diagram illustrating a part of an amplifier circuit in the first embodiment.

FIG. 12 is a diagram illustrating an output power PoutOCA with respect to Z2/Zo in simulation 1.

FIG. 13 is a diagram illustrating Z2/Zo with respect to PS6-PS7 in simulation 2.

FIG. 14 is a diagram illustrating Z2/Zo with respect to a division ratio in simulation 3.

FIG. 15 is a diagram illustrating Z2/Zo with respect to a Δ phase difference in simulation 4.

FIG. 16 is a Smith chart of impedances Z1, Z2, Z3a and Z3b in simulation 5.

FIG. 17 is a plan view illustrating a branch line coupler in the first embodiment.

FIG. 18 is a plan view illustrating a branch line coupler in the first embodiment.

FIG. 19 is another example of an amplifier circuit according to the first embodiment.

### DETAILED DESCRIPTION OF EMBODIMENTS

By making the powers of the two auxiliary amplifiers different from each other, a load impedance of the control amplifier can be set to different values depending on the power of the input signal. However, when the bias voltages supplied to the two auxiliary amplifiers are made different from each other in order to make the power of the two auxiliary amplifiers different from each other, the system is greatly affected because different bias voltages are prepared.

The present disclosure has been made in view of the above problems, and an object thereof is to set the load impedance of the control amplifier to a different value without affecting the system.

### Details of Embodiments of the Present Disclosure

First, the contents of the embodiments of this disclosure are listed and explained.

(1) A amplifier circuit according to the present disclosure includes a first divider that divides an input signal into a first signal and a second signal; a control amplifier that amplifies the first signal and outputs an amplified signal as a third signal; a second divider that divides the second signal into a fourth signal and a fifth signal having different phases at a center frequency of an operating band; a first auxiliary amplifier that amplifies the fourth signal and outputs an amplified signal as a sixth signal; a second auxiliary amplifier that amplifies the fifth signal and outputs an amplified signal as a seventh signal; and a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, and combines the sixth signal, the seventh signal and the third signal, and outputs a combined signal as the output signal; wherein the amplifier circuit satisfies at least one of following conditions a) to c), a) in the combiner, a first division ratio of amplitudes of powers of signals output to the fourth end and the third end when a signal at the center frequency is input to the first end is 0.5 dB or more; b) a second division ratio of amplitudes of powers of divided signals when a signal at the center frequency is input to the second divider is 0.5 dB or more; and c) a phase difference between the sixth signal input to the first end and the seventh signal input to the second end at the center frequency is 85° or less or 95° or more. This allows a load impedance of the control amplifier to be set to a different value.

(2) In the above (1), the first division ratio may be 0.5 dB or more. This allows a load impedance of the control amplifier to be set to a different value.

(3) In the above (1), the first division ratio may be 2 dB or more. This allows a load impedance of the control amplifier to be set to a different value.

(4) In the above (1), the second division ratio may be 0.5 dB or more. This allows a load impedance of the control amplifier to be set to a different value.

(5) In the above (1), the second division ratio may be 3 dB or more. This allows a load impedance of the control amplifier to be set to a different value.

(6) In the above (1), the phase difference may be 85° or less or 95° or more. This allows a load impedance of the control amplifier to be set to a different value.

(7) In the above (1), the phase difference may be 0° or more and 75° or less, or 105° or more and 180° or less. This allows a load impedance of the control amplifier to be set to a different value.

(8) In any one of the above (1) to (7), the amplifier circuit further may include a bias circuit that supplies a same bias voltage to the first auxiliary amplifier and the second auxiliary amplifier. A saturation power of the first auxiliary amplifier may be equal to a saturation power of the second auxiliary amplifier. This allows a load impedance of the control amplifier to be set to a different value.

(9) In any one of the above (1) to (8), the amplifier circuit further may include a matching circuit that matches an impedance at the center frequency viewed from the matching circuit toward the third end with an impedance at the center frequency viewed from the control amplifier toward the matching circuit. The control amplifier may operate in class AB or class B, and the first auxiliary amplifier and the second auxiliary amplifier may operate in class C, and an absolute value of a first impedance at the center frequency viewed from the matching circuit toward the third end when the first auxiliary amplifier and the second auxiliary amplifier operate may be 0.9 times or less or 1.1 times or more an absolute value of a second impedance at the center frequency viewed from the matching circuit toward the third end when the first auxiliary amplifier and the second auxiliary amplifier do not operate. This allows a load impedance of the control amplifier to be set to a different value.

(10) A amplifier circuit according to the present disclosure includes a first divider that divides an input signal into a first signal and a second signal; a control amplifier that operates in class AB or class B, amplifies the first signal, and outputs an amplified signal as a third signal; a second divider that divides the second signal into a fourth signal and a fifth signal having different phases at a center frequency of an operating band; a first auxiliary amplifier that operates in class C, amplifies the fourth signal, and outputs an amplified signal as a sixth signal; a second auxiliary amplifier that operates in class C, amplifies the fifth signal, outputs an amplified signal as a seventh signal, and has a saturation power equal to a saturation power of the first auxiliary amplifier; a bias circuit that supplies a same bias voltage to the first auxiliary amplifier and the second auxiliary amplifier; a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, combines the sixth signal, the seventh signal and the third signal, and outputs a combined signal as the output signal; and a matching circuit that matches an impedance at the center frequency viewed from the matching circuit toward the third end with an impedance at the center frequency viewed from the control amplifier toward the matching circuit; wherein an absolute value of a first impedance at the center frequency viewed from the matching circuit toward the third end when the first auxiliary amplifier and the second auxiliary amplifier operate is 0.9 times or less or 1.1 times or more an absolute value of a second impedance at the center frequency viewed from the matching circuit toward the third end when the first auxiliary amplifier and the second auxiliary amplifier do not operate. This allows a load impedance of the control amplifier to be set to a different value.

(11) In the above (9) or (10), the absolute value of the first impedance may be 1.5 times or more the absolute value of the second impedance. This allows a load impedance of the control amplifier to be set to a different value.

Specific examples of an amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

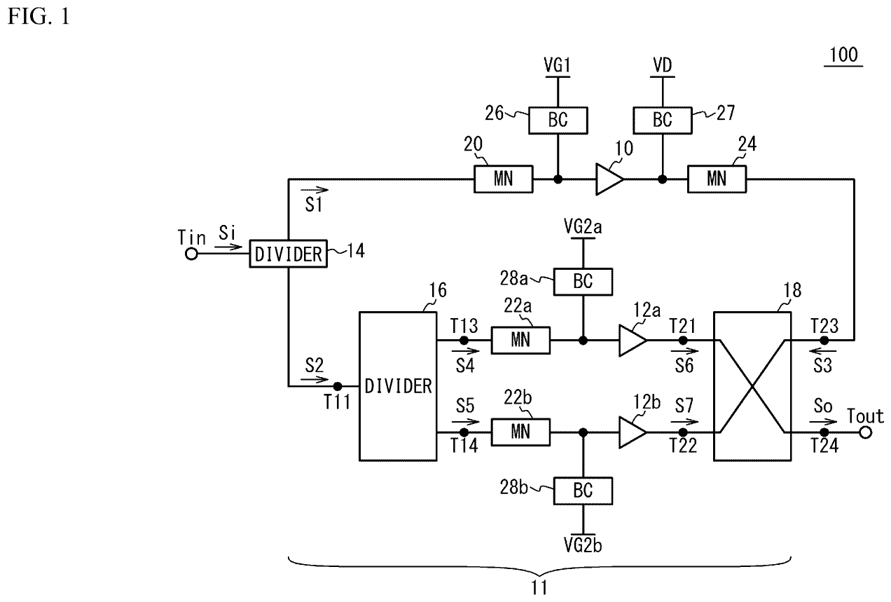

FIG. 1 is a circuit diagram of an amplifier circuit according to a first embodiment. As illustrated in FIG. 1, in an amplifier circuit 100 of the first embodiment, a control amplifier 10 and a balance amplifier 11 are connected in parallel between an input terminal Tin and an output terminal Tout. A high-frequency signal is input to the input terminal Tin as an input signal Si. When the amplifier circuit 100 is used in a base station for mobile communication, the frequency of the high-frequency signal is, for example, 0.5 GHz to 10 GHz. A divider 14 (first divider) divides the input signal Si input to the input terminal Tin into signals S1 (first signal) and S2 (second signal).

The signal S1 passes through a matching circuit 20 and is input to the control amplifier 10. Each of matching circuits are denoted as “MN (Matching network)” in FIG. 1. The matching circuit 20 matches an impedance viewed from the divider 14 toward the matching circuit 20 with an impedance viewed from the matching circuit 20 toward the control amplifier 10. A bias circuit (BC) 26 for supplying an input bias voltage VG1 to the control amplifier 10 is connected to a node in a line between the divider 14 and the control amplifier 10. The bias circuit 26 supplies the input bias voltage VG1 to the control amplifier 10, and suppresses leakage of the signal S1 to a power supply supplying the input bias voltage VG1.

The control amplifier 10 amplifies the signal S1 and outputs the amplified signal as a signal S3 (third signal). The signal S3 amplified by the control amplifier 10 passes through a matching circuit 24 and is input to an end T23 of a combiner 18. The matching circuit 24 matches an impedance viewed from the control amplifier 10 toward the matching circuit 24 with an impedance viewed from the matching circuit 24 toward the combiner 18. A bias circuit 27 for supplying an output bias voltage VD to the control amplifier 10 is connected to a node in a line between the control amplifier 10 and the combiner 18. The bias circuit 27 supplies the output bias voltage VD to the control amplifier 10, and suppresses leakage of the signal S3 to the power supply supplying the output bias voltage VD.

A signal S2 divided by the divider 14 is input to the balance amplifier 11. The balance amplifier 11 includes a divider 16, auxiliary amplifiers 12a and 12b, and the combiner 18. The divider 16 (second divider) divides the signal S2 input to an end T11 into signals S4 (fourth signal) and S5 (fifth signal), and outputs them from ends T13 and T14, respectively. The signal S5 is delayed in phase by, for example, about 90° from the phase of the signal S4. The amplitudes of the signals S5 and S4 are substantially the same as each other, for example. The angle 90° may not be strictly 90°, and may be, for example, 85° or more and 95° or less, or 88° or more and 92° or less. The same applies to the combiner 18.

The signal S4 passes through a matching circuit 22a and is input to the auxiliary amplifier 12a. The matching circuit 22a matches an impedance viewed from the divider 16 toward the matching circuit 22a with an impedance viewed from the matching circuit 22a toward the auxiliary amplifier 12a. A bias circuit 28a for supplying an input bias voltage VG2a to the auxiliary amplifier 12a is connected to a node in a line between the divider 16 and the auxiliary amplifier 12a. The bias circuit 28a supplies the input bias voltage VG2a to the auxiliary amplifier 12a, and suppresses leakage of the signal S4 to the power supply supplying the input bias voltage VG2a. The auxiliary amplifier 12a (first auxiliary amplifier) amplifies the signal S4 and outputs the amplified signal as a signal S6 (sixth signal). The signal S6 amplified by the auxiliary amplifier 12a is input to an end T21 of the combiner 18.

The signal S5 passes through a matching circuit 22b and is input to the auxiliary amplifier 12b. The matching circuit 22b matches an impedance viewed from the divider 16 toward the matching circuit 22b with an impedance viewed from the matching circuit 22b toward the auxiliary amplifier 12b. A bias circuit 28b for supplying an input bias voltage VG2b to the auxiliary amplifier 12b is connected to a node in a line between the divider 16 and the auxiliary amplifier 12b. The bias circuit 28b supplies the input bias voltage VG2b to the auxiliary amplifier 12b, and suppresses the leakage of the signal S5 to the power supply supplying the input bias voltage VG2b. The auxiliary amplifier 12b (second auxiliary amplifier) amplifies the signal S5 and outputs the amplified signal as a signal S7 (seventh signal). The signal S7 amplified by the auxiliary amplifier 12b is input to an end T22 of the combiner 18.

Matching circuits for matching impedances may be connected between the auxiliary amplifiers 12a and 12b and the combiner 18. In the first embodiment, the combiner 18 adjusts the loads of the auxiliary amplifiers 12a and 12b. For this reason, the matching circuits need not be provided between the auxiliary amplifiers 12a and 12b and the combiner 18. A harmonic processing circuit may be connected between the auxiliary amplifiers 12a and 12b and the combiner 18 to reflect harmonic signals in the signals S6 and S7. The harmonic signals are, for example, second harmonics or third harmonics when the operating frequency of the amplifier circuit is a fundamental harmonic. Bias circuits for supplying output bias voltages to the auxiliary amplifiers 12a and 12b may be provided between the auxiliary amplifiers 12a and 12b and the combiner 18. In the first embodiment, the output bias voltages of the auxiliary amplifiers 12a and 12b are supplied from the bias circuit 27 to the auxiliary amplifiers 12a and 12b through the combiner 18.

The combiner 18 is, for example, a branch line coupler. The ends T21 to T24 are terminals of the branch line coupler, and the ends T21 and T24 are located diagonally, and the ends T22 and T23 are located diagonally. The signal S6 is input to the end T21 (first end). The signal S7 is input to the end T22 (second end). The signal S3 is input to the end T23 (third end). An output signal So is output from the end T24 (fourth end). The combiner 18 combines the signals S3, S6 and S7 and outputs the combined signal as an output signal So.

The control amplifier 10 and the auxiliary amplifiers 12a and 12b are transistors such as FET (Field Effect Transistor), and the sources thereof are grounded, and high-frequency signals are input to the gates thereof and high-frequency signals are output from the drains thereof. The FET is, for example, a GaN HEMT (Gallium Nitride High Electron Mobility Transistor) or an LDMOS (Laterally Diffused Metal Oxide Semiconductor). Each of the control amplifier 10 and the auxiliary amplifiers 12a and 12b may be provided with multistage FETs. When the control amplifier 10 and the auxiliary amplifiers 12a and 12b are FETs, the input bias voltages VG1, VG2a and VG2b are gate bias voltages, and the output bias voltage VD is a drain bias voltage.

The control amplifier 10 corresponds to a main amplifier of the Doherty amplifier circuit, and the auxiliary amplifiers 12a and 12b correspond to peak amplifiers of the Doherty amplifier circuit. The control amplifier 10 operates in class AB or class B, and the auxiliary amplifiers 12a and 12b operate in class C. When the input power of the input signal Si is small, the control amplifier 10 mainly amplifies the input signal Si. When the input power is increased, the auxiliary amplifiers 12a and 12b amplify the peak of the input signal Si in addition to the control amplifier 10. As a result, the control amplifier 10 and the auxiliary amplifiers 12a and 12b amplify the input signal Si.

### Example of Divider 16

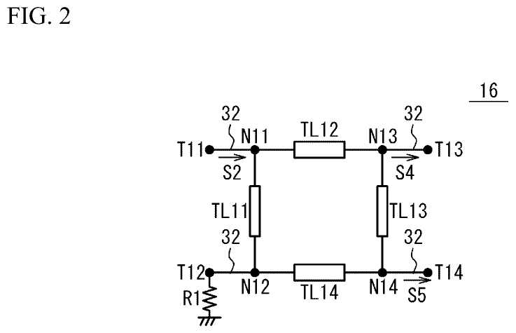

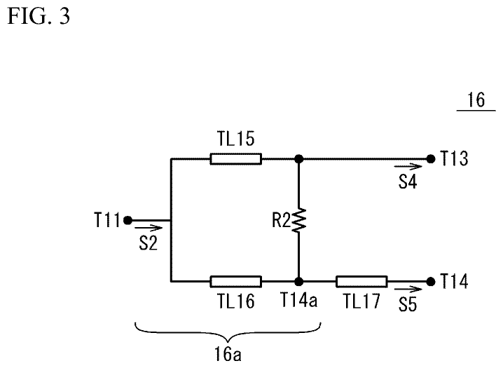

FIGS. 2 and 3 are circuit diagrams illustrating examples 1 and 2 of the divider 16 in a first embodiment. As illustrated in FIG. 2, in the example 1, the divider 16 uses a distributed constant type branch line coupler. Transmission lines TL11, TL12, TL13, and TL14 are connected between nodes N11 and N12, between nodes N11 and N13, between nodes N13 and N14, and between nodes N12 and N14, respectively. The transmission lines TL11 to TL14 are λ/4 transmission lines. The electrical length of the λ/4 transmission line is, for example, approximately λ/4. Here, λ is the wavelength of the center frequency fo of the operating band of the amplifier circuit 100. The electrical length of the λ/4 transmission line is not strictly limited to λ/4, and may be, for example, 3λ/16 or more and 5λ/16 or less, or 7λ/32 or more and 9λ/32 or less. The same applies to other λ/4 transmission lines. Transmission lines 32 are connected between the end T11 and the node N11, between the end T12 and the node N12, between the end T13 and the node N13, and between the end T14 and the node N14. The signal S2 input to the end T11 is divided into the signals S4 and S5, and the signals S4 and S5 are output from the ends T13 and T14, respectively. The phase of the center frequency fo of the signal S5 is delayed by approximately 90° from the phase of the center frequency fo of the signal S4. The end T12 is connected to a reference potential via a resistor R1. The resistance value of the resistor R1 is, for example, a reference impedance (for example, 50 Ω).

As illustrated in FIG. 3, in the example 2, the divider 16 is a Wilkinson divider 16a. The Wilkinson divider 16a includes transmission lines TL15 and TL16 and a resistor R2. The transmission line TL15 is connected between the end T11 and the end T13, and the transmission line TL16 is connected between the end T11 and an end T14a. The transmission lines TL15 and TL16 are, for example, λ/4 transmission lines. The resistance value of the resistor R2 is, for example, twice the reference impedance. A transmission line TL17 is connected between the end T14a and the end T14. The transmission line TL17 is a λ/4 transmission line. The Wilkinson divider 16a divides the signal S2 input to the terminal T11 into the signals S4 and S5 having substantially the same amplitude. The transmission line TL17 delays the phase of the signal S5 by approximately 90° from the phase of the signal S4.

The divider 16 may be a lumped constant type branch line coupler using inductors and capacitors, a distributed coupling type coupler in which two transmission lines are electromagnetically coupled, or a dense-wound coil coupler in which two inductors are electromagnetically coupled.

### Example of Combiner 18

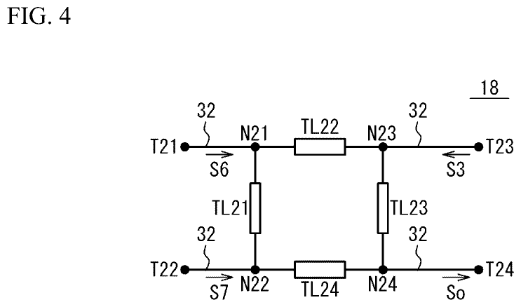

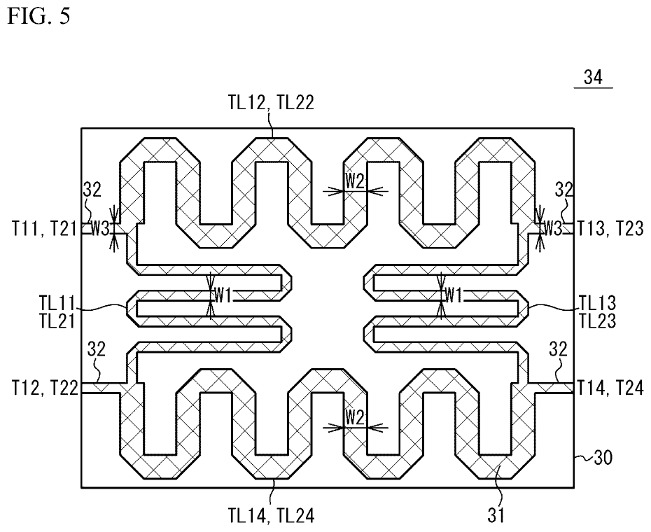

FIG. 4 is a circuit diagram illustrating an example of the combiner 18 in the first embodiment. As illustrated in FIG. 4, the combiner 18 is a distributed constant type branch line coupler. Transmission lines TL21, TL22, TL23, and TL24 are connected between nodes N21 and N22, between nodes N21 and N23, between nodes N23 and N24, and between nodes N22 and N24, respectively. The transmission lines TL21 to TL24 are λ/4 transmission lines. The transmission lines 32 are connected between the end T21 and the node N21, between the end T22 and the node N22, between the end T23 and the node N23, and between the end T24 and the node N24, respectively. The signal S6 input to the end T21, the signal S7 input to the end T22, and the signal S3 input to the end T23 are combined, and a combined signal is output from the end T24 as the output signal So.

The combiner 18 may be a lumped constant type branch line coupler using inductors and capacitors, a distributed coupling type coupler in which two transmission lines are electromagnetically coupled, or a dense-wound coil coupler in which two inductors are electromagnetically coupled.

FIG. 5 is a plan view of the branch line coupler in the first embodiment. As illustrated in FIG. 5, in a distributed constant type branch line coupler 34 used in the divider 16 and the combiner 18, the transmission lines TL11 to TL14, TL21 to TL24 and TL32 are formed by a conductor pattern 31 provided on a dielectric substrate 30. A metal layer to which the reference potential is supplied is provided on the lower surface of the dielectric substrate 30. The transmission lines TL11 to TL14, TL21 to TL24 and 32 are microstrip lines. The characteristic impedance of the transmission line 32 is a reference impedance Zo (e.g., 50 Ω). Each of the transmission lines TL11, TL13, TL21 and TL23 has a width W1, each of the transmission lines TL12, TL14, TL22 and TL24 has a width W2, and the transmission line 32 has a width W3. When the distributed constant type branch line coupler 34 is a 3 dB coupler (that is, a coupler having a division ratio and a combination ratio of 1), a characteristic impedance Zc1 of the transmission lines TL11, TL21, TL13, and TL23 is set to the reference impedance Zo, and a characteristic impedance Zc2 of the transmission lines TL12, TL22, TL14, and TL24 is set to 1/V 2 times the reference impedance Zo.

When the dielectric substrate 30 is a mounting substrate, the dielectric substrate 30 is, for example, a glass epoxy resin substrate or a ceramic substrate. In the case where the divider 16 and the combiner 18 are monolithically integrated with the control amplifier 10 and the auxiliary amplifiers 12a and 12b, the dielectric substrate 30 is, for example, a silicon carbide substrate, a gallium nitride substrate, a gallium arsenide substrate or a silicon substrate. The conductor pattern 31 is a metal layer such as a gold layer, a copper layer, or an aluminum layer.

The matching circuits 20, 22a, 22b, and 24 are passive circuits including inductors and capacitors, and are, for example, inductors connected in series, x-type circuits of CLC configuration, T-type circuits of LCL configuration, L-type circuits of LC configuration, or circuits combining these circuits.

### First Comparative Example

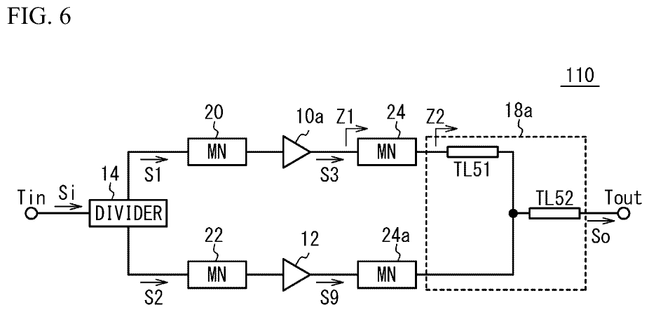

As a first comparative example, a Doherty amplifier circuit will be described. FIG. 6 is a circuit diagram of an amplifier circuit according to the first comparative example. As illustrated in FIG. 6, in an amplifier circuit 110 of the first comparative example, a main amplifier 10a and a peak amplifier 12 are provided in parallel between the input terminal Tin and the output terminal Tout. The divider 14 divides the input signal Si into the signals S1 and S2. The main amplifier 10a amplifies the signal S1 that has passed through the matching circuit 20, and outputs the amplified signal as the signal S3 to a combiner 18a via the matching circuit 24. The peak amplifier 12 amplifies the signal S2 that has passed through a matching circuit 22, and outputs the amplified signal as a signal S9 to the combiner 18a via a matching circuit 24a.

The combiner 18a includes λ/4 transmission lines TL51 and TL52 as impedance converters. An impedance viewed from the matching circuit 24 toward the combiner 18a and a load impedance of the peak amplifier 12 are modulated using the λ/4 transmission lines TL51 and TL52.

In the first comparative example, when the frequency is changed, the electric length of the λ/4 transmission line is shifted from λ/4, and therefore it is difficult to widen the operating band. In one example, the specific bandwidth of the combiner using the λ/4 transmission lines TL51 and TL52 is about 8%. In the LMBA of the first embodiment, since the branch line coupler is used to modulate the load impedance of the auxiliary amplifiers 12a and 12b, the operating band can be widened. The specific bandwidth of the branch line coupler is, for example, 120% at the maximum in a commercially available hybrid coupler. In this way, the LMBA allows the combiner 18 to have a wider bandwidth.

### Second Comparative Example

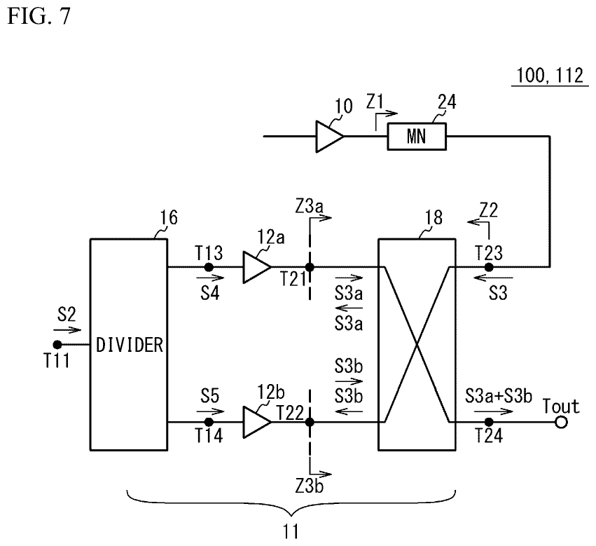

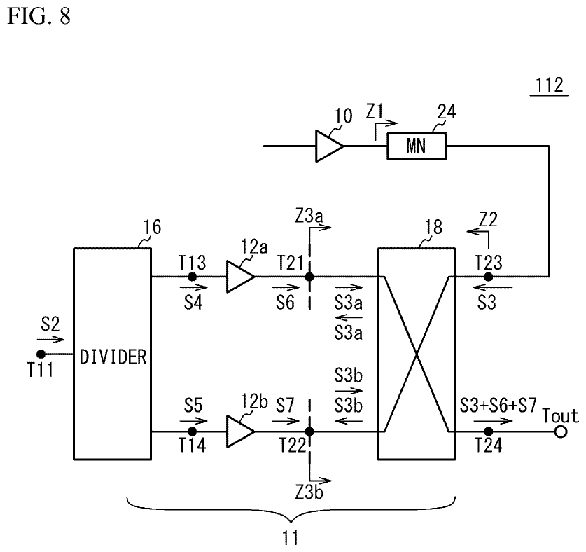

FIG. 7 is a circuit diagram illustrating a part of the amplifier circuit in a second comparative example and the first embodiment. FIG. 8 is a circuit diagram illustrating a part of an amplifier circuit in the second comparative example. FIGS. 7 and 8 illustrate circuits of the control amplifier 10 and the balance amplifier 11 and subsequent circuits. In the second comparative example, all of the following three conditions are satisfied.

Condition 1: The division ratio of the powers that the divider 16 divides the signal S2 into the signals S4 and S5 is 1:1.

Condition 2: The combination ratio of the powers at which the combiner 18 combines the signals S6 and S7 is 1:1.

Condition 3: The phase of the signal S7 input to the combiner 18 is delayed by 90° from the phase of the signal S6.

A description will be given of a case where the power of the input signal Si is small and the auxiliary amplifiers 12a and 12b do not operate, with reference to FIG. 7. As illustrated in FIG. 7, in an amplifier circuit 112 of the second comparative example, the signal S3 input from the end T23 to the combiner 18 is divided into two signals S3a and S3b at the ends T21 and T22. The ratio of the amplitudes of the powers of the signals S3a and S3b is 1:1 according to the condition 2. The phase of the signal S3b at the end T22 is delayed by 90° from the phase of the signal S3a at the end T21. The signals S3a and S3b are reflected at ends T21 and T22, respectively. The reflected signals S3a and S3b are combined at the end T24. The phase of the signal S3a reflected at the end T21 is delayed by 90° from the phase of the signal S3b reflected at the end T22. As a result, the phases of the signals S3a and S3b are aligned at the end T24 to combine the signal S3. The combined signal S3 is output to the output terminal Tout as the output signal So. At this time, the reflection coefficient (i.e., the absolute values of the impedances Z3a and Z3b) viewed from the auxiliary amplifiers 12a and 12b toward the combiner 18 is greater than 1, and impedances Z3a and Z3b serving as the loads of the auxiliary amplifiers 12a and 12b are substantially high. On the other hand, an impedance Z2 viewed from the matching circuit 24 toward the end T23 is the reference impedance (e.g., 50 Ω) which is an input impedance of the end T23.

Next, a description will be given of a case where the power of the input signal Si is large and the auxiliary amplifiers 12a and 12b operate, with reference to FIG. 8. As illustrated in FIG. 8, in the amplifier circuit 112 of the second comparative example, the phase of the signal S7 is delayed by 90° from that of the signal S6. The phase of the signal S3b at the end T22 is delayed by 90° from that of the signal S3a at the end T21. Accordingly, by appropriately adjusting a phase difference between the signals S1 and S2 in FIG. 1, the phases of the signals S6 and S3a at the end T21 are optimized (for example, the phases of the signals S6 and S3a are aligned), and the phases of the signals S7 and S3b at the end T22 are optimized (for example, the phases of the signals S7 and S3b are aligned). A signal S6+S3a combined at the end T21 and a signal S7+S3b combined at the end T22 are combined at the end T24. A combined signal S3+S6+S7 is output to the output terminal Tout as the output signal So.

At this time, the signals incident from the auxiliary amplifiers 12a and 12b to the ends T21 and T22 are substantially the signals S6+S3a and S7+S3b, respectively, and the signals reflected at the ends T21 and T22 are substantially the signals S3a and S3b, respectively. Therefore, the reflection coefficients (i.e., the absolute values of the impedances Z3a and Z3b) of the auxiliary amplifiers 12a and 12b at the ends T21 and T22 are smaller than 1, and the larger the amplitudes of the powers of the signals S6 and S7 are, the smaller the reflection coefficients become. The impedances Z3a and Z3b, which are the loads of the auxiliary amplifiers 12a and 12b, become substantially lower as the amplitudes of the powers of the signals S6 and S7 increase. In this way, the combiner 18 modulates the impedances Z3a and Z3b, which are the loads viewed from the auxiliary amplifiers 12a and 12b toward the combiner 18, depending on the amplitudes of the signals S6 and S7. On the other hand, the impedance Z2 from the matching circuit 24 toward the end T23 is the reference impedance (for example, 50 Ω) regardless of the magnitude of the amplitudes of the signals S6 and S7.

When the power of the output signal So is a maximum value in the operation range of the amplifier circuit, the output power of the output signal So is defined as a saturation power Psat. At the saturation power Psat, the output powers of the main amplifier 10a and the peak amplifier 12 in the first comparative example, and the output powers of the control amplifier 10 and the auxiliary amplifiers 12a and 12b in the second comparative example are saturated. The saturation of the output power includes a state where the output power is low in the range of 1 dB or less or 2 dB or less from a complete saturation state. When the power of the output signal So is a minimum value in the operation range of the amplifier circuit, the power is set to the back-off power Pbo. At the back-off power Pbo, the output power of the main amplifier 10a starts to be saturated in the first comparative example, and the output power of the control amplifier 10 is saturated in the second comparative example. The impedance viewed from the main amplifier 10a or the control amplifier 10 toward the matching circuit 24 is defined as Z1, and the impedance viewed from the matching circuit 24 toward the combiner 18a or 18 is defined as Z2.

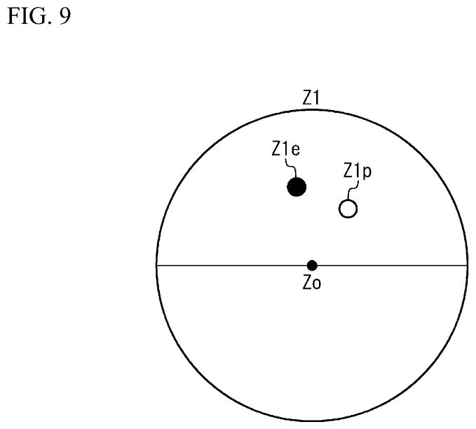

FIG. 9 is a Smith chart illustrating the impedance Z1 in the first comparative example, the second comparative example, and the first embodiment. The center of the circle corresponds to the reference impedance Zo, and the circumference corresponds to the absolute value of the impedance Z1/Zo being 1. An impedance Z1e is a load impedance Z1 at which the efficiencies of the main amplifier 10a and the control amplifier 10 are optimum. An impedance Z1p is a load impedance Z1 at which the output powers of the main amplifier 10a and the control amplifier 10 are optimum. Note that the impedances Z1e and Z1p in FIG. 9 are schematic examples.

In the first comparative example, the impedance Z2 viewed from the matching circuit 24 toward the combiner 18a differs between when the output power Pout of the output signal So is the saturation power Psat and when it is the back-off power Pbo. Therefore, by appropriately designing the matching circuit 24, the impedance Z1 can be set to Z1p when the output power Pout is the saturation power Psat, and the impedance Z1 can be set to Z1e when the output power Pout is the back-off power Pbo. The matching circuit 24 is designed so that the efficiency and the output power are compatible when the output power Pout at which the peak amplifier 12 is saturated is the power Pbo.

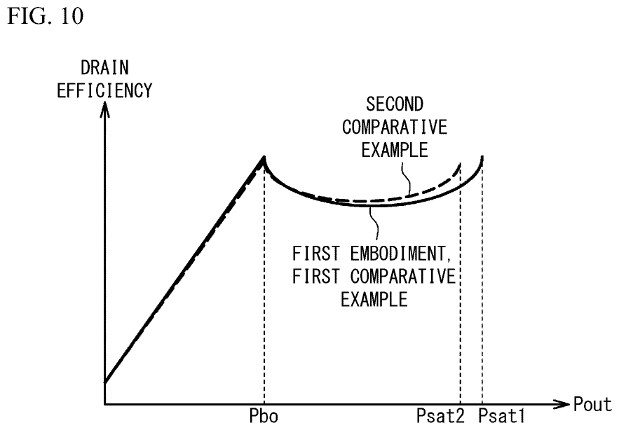

FIG. 10 is a graph illustrating drain efficiency with respect to output power in the first comparative example, the second comparative example, and the first embodiment. When the output power Pout is equal to the back-off power Pbo and the saturation power Psat, the drain efficiency is maximized. In the first comparative example, when the output power Pout is the saturation power Psat, the impedance Z1 is the impedance Z1p at which the output power of the main amplifier 10a is optimized, and therefore the output power Pout becomes the large Psat1.

On the other hand, in the second comparative example, the impedance Z2 viewed from the matching circuit 24 toward the combiner 18 is the same between when the output power Pout is the saturation power Psat and when the output power Pout is the back-off power Pbo. Therefore, the impedance Z1 is the same when the output power Pout is either the saturation power Psat or the back-off power Pbo. With emphasis on efficiency at saturation power Psat, the matching circuit 24 is designed so that the impedance Z1 is Z1e in FIG. 9.

In FIG. 10, in the second comparative example, since the impedance Z1 of the control amplifier 10 is Z1e, which optimizes the efficiency when the output power Pout is the back-off power Pbo, the drain efficiency is substantially the same as that in the first comparative example. When the output power Pout is the saturation power Psat, the impedance Z1 of the control amplifier 10 is in the state of Z1e where the efficiency is optimized, and the output power Pout is equal to Psat2 which is smaller than Psat1 of the first comparative example. As described above, the saturation power Psat of the second comparative example is smaller than that of the first comparative example. Therefore, in the second comparative example, a back-off amount is reduced, and a dynamic range is reduced.

In the second comparative example, if the matching circuit 24 is designed so that the impedance Z1 of the control amplifier 10 is in the state of Z1p where the output power is optimized when the output power Pout is the saturation power Psat, the saturation power Psat can be made to be substantially the same as that of the first comparative example, but the drain efficiency at the saturation power Psat is lower than the drain efficiency of the first comparative example. As described above, the characteristics of the second comparative example are deteriorated as compared with the first comparative example.

### Description of First Embodiment

In the first embodiment, at least one of the conditions 1 to 3 is not satisfied. When the power of the input signal Si is small and the auxiliary amplifiers 12a and 12b do not operate, the impedance viewed from the matching circuit 24 toward the end T23 is the reference impedance (for example, 50 Ω) which is the input impedance of the end T23, as described with reference to FIG. 7.

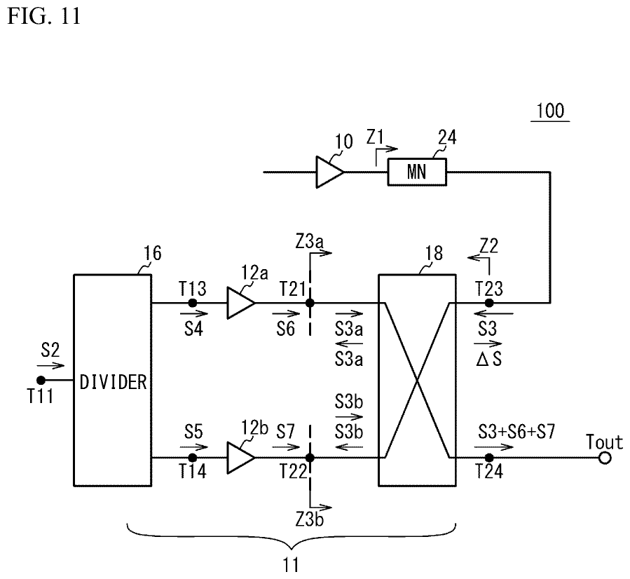

FIG. 11 is a circuit diagram illustrating a part of the amplifier circuit in the first embodiment. A description will be given of a case where the power of the input signal Si is large and the auxiliary amplifiers 12a and 12b operate, with reference to FIG. 11. In the first embodiment, at least one of the following conditions A to C is satisfied.

Condition A: The division ratio of the powers that the divider 16 divides the signal S2 into the signals S4 and S5 is not 1:1.

Condition B: The combination ratio of the powers at which the combiner 18 combines the signals S6 and S7 is not 1:1.

Condition C: The phase difference between the signals S7 and S6 input to the combiner 18 is not 90°.

When the condition A is satisfied and the conditions B and C are not satisfied, the ratio of the amplitudes of the powers of the signals S6 and S7 are not 1:1. Therefore, the power of the signal output from the end T23 of the combiner 18 is not zero, and a signal AS is output from the end T23. The signal AS output from the terminal T23 is reflected by the control amplifier 10 and returns to the terminal T23. Therefore, the signal output from the terminal T24 is S3+S6+S7.

When the condition B is satisfied and the conditions A and C are not satisfied, the ratio of the amplitudes of the powers of the signals S6 and S7 are 1:1, but the power of the signal output from the end T23 of the combiner 18 is not zero, and the signal A S is output from the end T23. The signal output from the terminal T24 is S3+S6+S7.

When the condition C is satisfied and the conditions A and B are not satisfied, the ratio of the amplitudes of the powers of the signals S6 and S7 are 1:1, but the power of the signal output from the end T23 of the combiner 18 is not zero, and the signal AS is output from the end T23. The signal output from the terminal T24 is S3+S6+S7.

The signal incident from the matching circuit 24 to the terminal T23 is S3, and the signal output from the terminal T23 (i.e., the reflected signal) is AS. Therefore, the impedance Z2 viewed from the matching circuit 24 toward the end T23 becomes higher than the reference impedance.

As described above, the impedance Z2 viewed from the matching circuit 24 to the combiner 18 is different between when the output power Pout of the output signal So is the saturation power Psat and when the output power Pout of the output signal So is the back-off power Pbo. Therefore, as illustrated in FIG. 9, by appropriately designing the matching circuit 24, the impedance Z1 can be set to Z1p when the output power Pout is the saturation power Psat, and the impedance Z1 can be set to Z1e when the output power Pout is the back-off power Pbo.

As illustrated in FIG. 10, in the first embodiment, when the output power Pout is the back-off power Pbo and the saturation power Psat, the drain efficiency of the control amplifier 10 is maximized. When the output power Pout is the saturation power Psat, the impedance Z1 is the impedance Z1p at which the output power of the control amplifier 10 is optimized, and therefore the output power Pout becomes the large Psat1. As described above, the saturation power Psat of the first embodiment is larger than that of the second comparative example, and can be set to be about the same as that of the first comparative example. Therefore, the back-off amount of the first embodiment is larger than that of the second comparative example, and the dynamic range can be increased. Since the branch line coupler is used for the combiner 18, the bandwidth of the combiner 18 can be increased as compared with the first comparative example.

### Simulation

In the first embodiment, a simulation was performed to see to what extent the impedance Z2 can be modulated under the conditions A, B, and C. The control amplifier 10 and the auxiliary amplifiers 12a and 12b are GaN HEMTs. The frequency of the signal is 3.5 GHz.

### Simulation 1

First, it was verified that the output power of the control amplifier 10 did not change as the impedance Z2 changed. When the impedance Z2 at the back-off power Pbo was the reference impedance Zo (50 Ω) and the output power Pout was the saturation power Psat, the output power PoutOCA at the time of saturation of the control amplifier 10 was simulated by changing the impedance Z2.

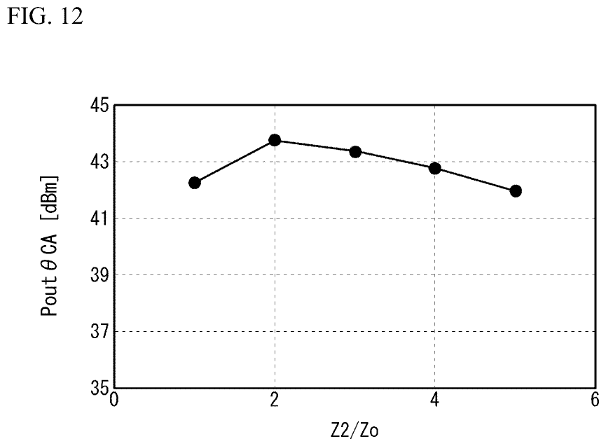

FIG. 12 is a diagram illustrating the output power PoutOCA with respect to Z2/Zo in the simulation 1. A horizontal axis represents the impedance Z2 normalized by the reference impedance Zo. A vertical axis represents the output power PoutOCA of the control amplifier 10. Dots indicate simulated points, and straight lines are lines connecting the dots. The same applies to the following figures. As illustrated in FIG. 12, even when Z2/Zo is changed from 1 to 5, the output power PoutOCA is 42 dBm or more. As described above, the change in the output power PoutOCA is small even when the impedance Z2 is changed, and the impedance Z2 under the conditions A, B and C can be simulated.

### Simulation 2

The impedance Z2 was simulated in the case where the condition A was satisfied but the conditions B and C were not satisfied. As the condition A, the ratio of the amplitudes of the powers of the signals S4 and S5 was assumed to be the same as the ratio of the amplitudes of the powers of the signals S6 and S7, and the impedance Z2 was simulated by changing the ratio of the amplitudes of the powers of the signals S6 and S7. The output power of the auxiliary amplifier 12a is the saturation power, and is set to about 43 dBm.

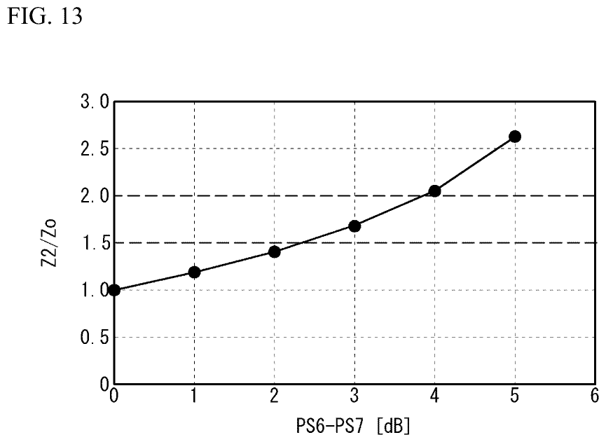

FIG. 13 is a diagram illustrating Z2/Zo with respect to PS6-PS7 in the simulation 2. PS6 and PS7 are the amplitudes of the powers of the signals S6 and S7, respectively. A horizontal axis represents PS6-PS7 in dB. A vertical axis represents Z2/Zo.

As illustrated in FIG. 13, when PS6-PS7 is 0 dB, Z2/Zo is 1 and the impedance Z2 is the reference impedance Zo. Z2/Zo increases as PS6-PS7 increases. That is, the impedance Z2 becomes larger than the reference impedance Zo. In this way, when the output power Pout is the saturation power Psat, the impedance Z2 can be made larger than the back-off power Pbo. In a symmetric Doherty amplifier circuit, the ratio of the impedance Z2 between the saturation power Psat and the back-off power Pbo is twice. Therefore, in order to modulate the impedance Z2 as much as the Doherty amplifier circuit, the value of PS6-PS7 is about 4 dB or more. If the ratio of the impedance Z2 between the saturation power Psat and the back-off power Pbo is 1.5 times, the impedance PS6-PS7 is about 2 dB or more when the impedance Z1 can be set to Z1e and Z1p in FIG. 9. The ratio of the amplitudes of the powers between the signals S4 and S5 is 2 dB or more or 4 dB or more, assuming that it is the same as PS6-PS7.

### Simulation 3

The impedance Z2 was simulated in a case where the condition B was satisfied but the conditions A and C were not satisfied. The ratio of the signal S6 input to the terminal T21 to be divided into the terminals T23 and T24 is expressed in dB, and is defined as the division ratio. The division ratio is positive when the signal output to the terminal T23 is large, and is negative when the signal output to the terminal T24 is large.

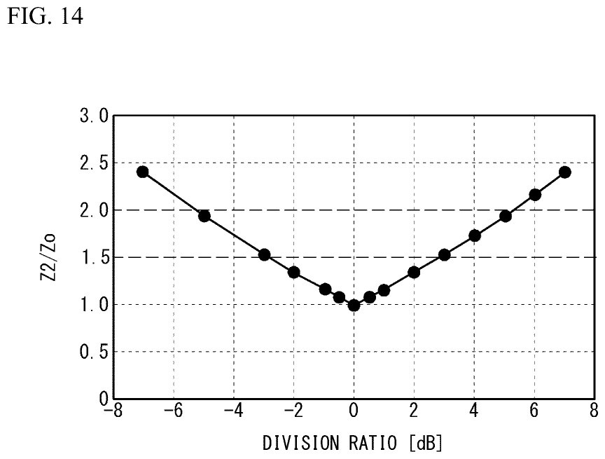

FIG. 14 is a graph illustrating Z2/Zo with respect to the division ratio in the simulation 3. The division ratio is expressed in dB. As illustrated in FIG. 14, when the division ratio is 0 dB, Z2/Zo is 1 and the impedance Z2 is the reference impedance Zo. As the division ratio increases positively and negatively, Z2/Zo increases. In order to set Z2/Zo to 1.5 or more, the division ratio is 3 dB or more or −3 dB or less, and in order to set Z2/Zo to 2 or more, the division ratio is 5 dB or more or −5 dB or less.

### Simulation 4

The impedance Z2 was simulated in a case where the condition C was satisfied but the conditions A and B were not satisfied. When the condition C is not satisfied, the phase of the signal S7 input to the end T22 is delayed by 90° from the phase of the signal S6 input to the end T21. Therefore, the deviation of the difference between the phases of the signals S6 and S7 from 90° was defined as the A phase difference.

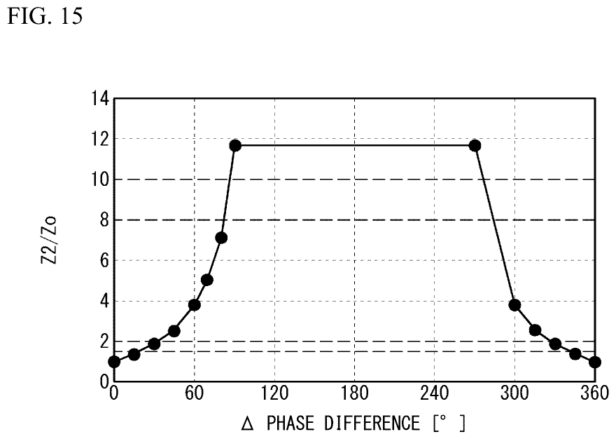

FIG. 15 is a diagram illustrating Z2/Zo with respect to the A phase difference in simulation 4. As illustrated in FIG. 15, when the A phase difference is 0° and 360°, Z2/Zo is 1 and the impedance Z2 is the reference impedance. Z2/Zo increases as the A phase difference increases from 0° and decreases from 360°. In order to set Z2/Zo to 1.5 or more, the A phase difference is 15° or more and 345° or less (that is, −15° or less), and in order to set Z2/Zo to 2 or more, the A phase difference is 30° or more and 330° or less (that is, −30° or less). When the upper limit of Z2/Zo is 8 or 10, the A phase difference is 80° or less or 90° or less.

### Simulation 5

As illustrated in the simulations 2 to 4, by changing the A phase difference, Z2/Zo can be changed to the maximum. Accordingly, each impedance was simulated in a case where the condition C was satisfied but the conditions A and B were not satisfied. The power of the input signal Si was changed so that the A phase difference was 45° and the output power Pout was changed from 25 dBm to 48 dBm.

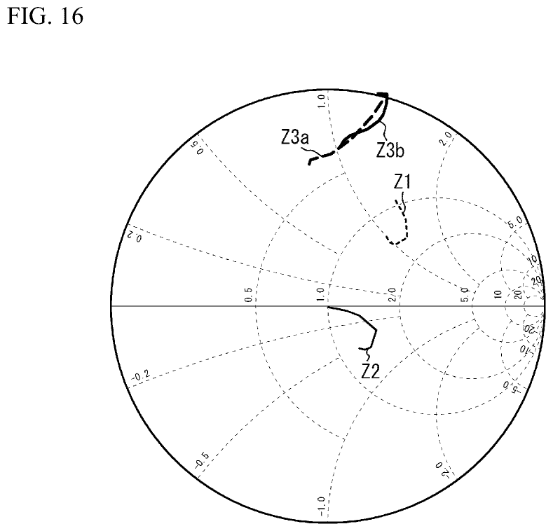

FIG. 16 is a Smith chart of the impedances Z1, Z2, Z3a and Z3b in simulation 5. As illustrated in FIG. 16, when the output power Pout is small, the impedances Z3a and Z3b are located near the periphery of the Smith chart, and the reflection coefficients viewed from the auxiliary amplifiers 12a and 12b toward the ends T21 and T22 are 1 or more. As the output power Pout increases, the absolute values of the impedances Z3a and Z3b decrease and the impedances Z3a and Z3b are located inside the circle of the Smith chart. Since the phase difference between the signals S6 and S7 is not 90°, the loci of the impedances Z3a and Z3b on the Smith chart are not the same as each other.

When the output power Pout is small, the impedance Z2 is the reference impedance and is 50 Ω. As the output power Pout increases, the impedance Z2 changes, and the absolute value of the impedance Z2 increases. Since the impedance Z2 changes depending on the output power Pout, the impedance Z1 also changes depending on the output power Pout.

In the simulation 5, since the matching circuit 24 is not appropriately designed, the locus of the impedance Z2 is not on the real axis of the Smith chart, but if the matching circuit 24 is appropriately designed, the locus of the impedance Z2 is close to the real axis. By appropriately designing the matching circuit 24, the impedance Z2 can be set to the position of Z1p in FIG. 9 when the output power Pout is the back-off power Pbo, and the impedance Z2 can be set to the position of Z1e in FIG. 9 when the output power Pout is the saturation power Psat.

In the simulations 2 to 5, the case where any one of the conditions A, B, and C is satisfied has been described. The conditions A and B may be satisfied, and the condition C need not be satisfied. The conditions B and C may be satisfied, and the condition A need not be satisfied. The conditions A and C may be satisfied, and the condition B need not be satisfied. The conditions A, B and C may be satisfied.

If the division ratio of the powers is different from 1:1, the division ratio represented in dB is different from 0 dB. When manufacturing and measurement errors are taken into account, the division ratio is 0.5 dB or more. When the division ratio is the amplitude ratio of the power of the larger signal to the smaller signal in the divided signals, the division ratio is 0 dB or more in dB representation. If the phase difference differs from 90°, the phase difference is 85° or less or 95° or more, taking into account the manufacturing and measurement errors.

Therefore, in the first embodiment, at least one of the following three conditions A to C is satisfied.

Condition A: When a signal at the center frequency fo of the operating band in the combiner 18 is input to the terminal T21, a first division ratio of the amplitudes of the powers of the signals output to the terminals T23 and T24 is 0.5 dB or more.

Condition B: A second division ratio of the amplitude of the powers of the divided signals when the signal at the center frequency fo is input to the divider 16 is 0.5 dB or more.

Condition C: The phase difference between the signal S6 input to the end T21 and the signal S7 input to the end T22 of the combiner 18 at the center frequency fo is 85° or less or 95° or more.

As a result, the impedance Z2 changes depending on the output power Pout. Therefore, the impedance Z1 can be set to a different value at a different output power Pout. For example, the matching circuit 24 is designed so that the impedance Z1 becomes Z1p at the saturation power Psat and the impedance Z1 becomes Z1e at the back-off power Pbo. As a result, as illustrated in FIG. 10, the characteristics of the amplifier circuit 100 can be improved as compared with the second comparative example. Further, by using the branch line coupler as the combiner 18, the bandwidth of the combiner 18 can be increased, and the bandwidth of the amplifier circuit 100 can be increased as compared with the first comparative example.

Furthermore, in the case where the bias voltages supplied to the two auxiliary amplifiers are made different from each other as in the case of Patent Document 1, since different bias voltages are prepared, the influence on the system (for example, a base station) becomes large. In the first embodiment, the bias voltages supplied to the two auxiliary amplifiers may be the same as each other. This can reduce the influence on the system.

As illustrated in FIG. 13 of the simulation 2, in order to increase the impedance Z2 at the saturation power Psat, the first division ratio can be set to 2 dB or more, 3 dB or more, or 4 dB or more. If the first division ratio is too large, it is difficult to design the matching circuit. From this viewpoint, the first division ratio can be set to 10 dB or less.

As illustrated in FIG. 14 of the simulation 3, in order to increase the impedance Z2 at the saturation power Psat, the second division ratio can be set to 3 dB or more, 4 dB or more, or 5 dB or more. If the second division ratio is too large, it is difficult to design the matching circuit. From this viewpoint, the second division ratio can be set to 10 dB or less.

As illustrated in FIG. 15 of the simulation 4, in order to increase the impedance Z2 at the saturation power Psat, the phase difference between the signals S6 and S7 can be set to 75° or less or 105° or more, 60° or less or 120° or more, or 45° or less or 135° or more. If the phase difference is too large, the power of the signal S6+S7 output to the terminal T24 becomes small. From this viewpoint, the phase difference can be set to be 0° or more and 75° or less, or 105° or more and 180° or less.

The bias circuits 28a and 28b of FIG. 1 supply the same input bias voltages VG2a and VG2b to the auxiliary amplifiers 12a and 12b, respectively. The bias circuit 27 supplies the same output bias voltage VD to the auxiliary amplifiers 12a and 12b. This eliminates the need to supply different bias voltages to the auxiliary amplifiers 12a and 12b. Therefore, the influence on the system can be reduced. The same bias voltage (or substantially the same bias voltage) allows a difference in bias voltage due to voltage drop of the wiring or the like. For example, the difference between the bias voltages of the auxiliary amplifiers 12a and 12b is 0.1 times or less or 0.05 times or less the total bias voltage.

The physical size of the auxiliary amplifier 12a is the same as the physical size of the auxiliary amplifier 12b. For example, when the auxiliary amplifiers 12a and 12b are FETs, the gate width of the auxiliary amplifier 12a is equal to the gate width of the auxiliary amplifier 12b. At this time, the saturation power of the auxiliary amplifier 12a and the saturation power of the auxiliary amplifier 12b at the same bias voltage are equal to each other. This makes it possible to make the configurations of the matching circuits 22a and 22b the same, and thus to facilitate the design of the amplifier circuit 100. The term “the saturation power is equal (or substantially equal)” means that a difference in saturation power due to manufacturing errors and the like is allowed. For example, the difference in saturation power between the auxiliary amplifiers 12a and 12b is 1 dB or less or 0.5 dB or less.

The absolute value of the first impedance Z2a viewed from the matching circuit 24 toward the end T23 when the auxiliary amplifiers 12a and 12b operate (at the time of the saturation power Psat) is different from the absolute value of the second impedance Z2b viewed from the matching circuit 24 toward the end T23 when the auxiliary amplifiers 12a and 12b do not operate (for example, at the time of the back-off power Pbo). In consideration of manufacturing errors and measurement errors, the absolute value of the first impedance Z2a is 0.9 times or less or 1.1 times or more, or 0.8 times or less or 1.2 times or more the absolute value of the second impedance Z2b. Accordingly, by appropriately setting the matching circuit 24, the impedance Z1 can be set to a different value at the time of a different output powers Pout.

In the Doherty amplifier circuit, the absolute value of the first impedance Z2a at the saturation power Psat is about twice the absolute value of the second impedance Z2b at the back-off power Pbo. Accordingly, if the absolute value of the first impedance Z2a is 1.5 times or more the absolute value of the second impedance Z2b, the impedance Z1 can be set to a different value. The absolute value of the first impedance Z2a can be two times or more, or three times or more the absolute value of the second impedance Z2b. If the difference between the first impedance Z2a and the second impedance Z2b is too large, it becomes difficult to design the matching circuit 24. From this viewpoint, the absolute value of the first impedance Z2a can be set to 10 times or less the absolute value of the second impedance Z2b.

### Method of Satisfying Conditions A and B

A method of satisfying the conditions A and B will be described. As illustrated in FIGS. 2 and 4, a description will be given of a case where distributed constant type branch line couplers are used for the divider 16 and the combiner 18. In FIGS. 2 and 4, when the division ratio at which the signals input from the ends T11 and T21 are divided into the ends T13 and T23 and the ends T14 and T24 is 0 dB, the characteristic impedance Zc1 of the transmission lines TL11, TL13, TL21 and TL23 is the reference impedance Zo, and the characteristic impedance Zc2 of the transmission lines TL12, TL14, TL22 and TL24 is a reference impedance/√2. For example, when the reference impedance Zo is 50 Ω, the characteristic impedance Zc1 is 50 Ω and the characteristic impedance Zc2 is 35.35 Ω.

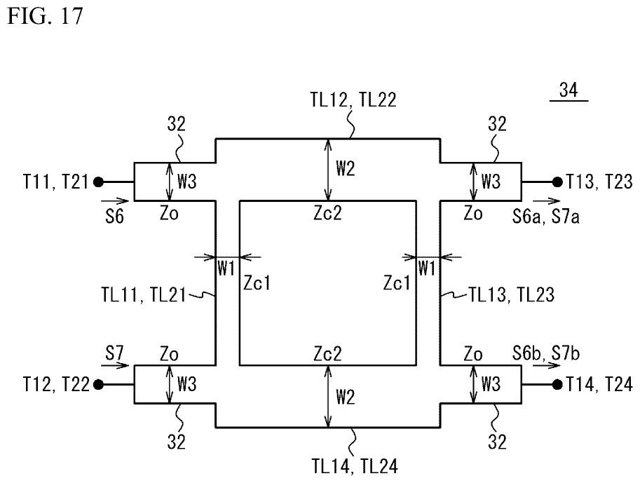

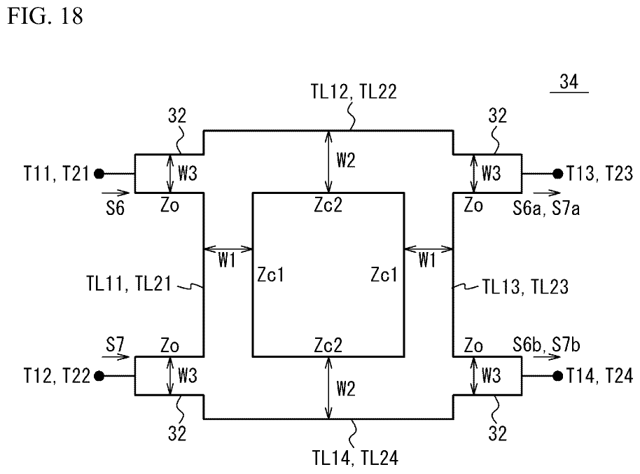

FIGS. 17 and 18 are plan views illustrating the branch line coupler in the first embodiment. The signals S6 input to the ends T11 and T21 are divided into the ends T13 and T23 and the ends T14 and T24 as the signals S6a and S6b, respectively. The signals S7 input to the ends T12 and T22 are divided into the ends T13 and T23 and the ends T14 and T24 as the signals S7a and S7b, respectively.

A description will be given of a case where the amplitude of the power of the signal S6a is made larger than the amplitude of the power of the signal S6b and the amplitude of the power of the signal S7b is made larger than the amplitude of the power of the signal S7a. As illustrated in FIG. 17, the characteristic impedance Zc1 of each of the transmission lines TL11, TL13, TL21 and TL23 is made larger than the reference impedance Zo. Therefore, the width W1 of each of the transmission lines TL11, TL13, TL21, and TL23 is smaller than the width W3 of each of the transmission lines 32. The characteristic impedance Zc2 of each of the transmission lines TL12, TL14, TL22 and TL24 is made lower than Zc1/√2 and lower than the reference impedance Zo. Therefore, the width W2 of each of the transmission lines TL12, TL14, TL22 and TL24 is larger than the width W3 of each of the transmission lines 32. For example, when the amplitude of the power of the signal S6a is made larger than the amplitude of the power of the signal S6b by 3 dB and the amplitude of the power of the signal S7b is made larger than the amplitude of the power of the signal S7a by 3 dB, the characteristic impedance Zc1 is set to 70.6 Ω and the characteristic impedance Zc2 is set to 40.80 Ω.

A description will be given of a case where the amplitude of the power of the signal S6b is made larger than the amplitude of the power of the signal S6a and the amplitude of the power of the signal S7a is made larger than the amplitude of the power of the signal S7b. As illustrated in FIG. 18, the characteristic impedance Zc1 of each of the transmission lines TL11, TL13, TL21 and TL23 is made smaller than the reference impedance Zo. Therefore, the width W1 of each of the transmission lines TL11, TL13, TL21, and TL23 is larger than the width W3 of each of the transmission lines 32. The characteristic impedance Zc2 of each of the transmission lines TL12, TL14, TL22 and TL24 is made higher than Zc1/√2. Therefore, the width W2 of each of the transmission lines TL12, TL14, TL22, and TL24 is larger than the width W3 of each of the transmission lines 32. For example, when the amplitude of the power of the signal S6b is made larger than the amplitude of the power of the signal S6a by 3 dB and the amplitude of the power of the signal S7a is made larger than the amplitude of the power of the signal S7b by 3 dB, the characteristic impedance Zc1 is set to 35.4 Ω and the characteristic impedance Zc2 is set to 28.89 Ω.

As described above, from the viewpoint of increasing the first division ratio or the second division ratio, the characteristic impedance Zc1 can be set to 1.01 times or more, 1.2 times or more, 1.4 times or more, or 1.7 times or more the reference impedance Zo. Alternatively, the characteristic impedance Zc1 can be set to 0.99 times or less, 0.85 times or less, 0.7 times or less, or 0.6 times or less the reference impedance Zo. From the viewpoint of not making the first division ratio or the second division ratio too large, the characteristic impedance Zc1 can be set to 3 times or less the reference impedance Zo, or to 0.5 times or more the reference impedance Zo.

When the characteristic impedance Zc1 is larger than the reference impedance Zo, the characteristic impedance Zc2 can be set to 0.99 times or less, 0.95 times or less, or 0.9 times or less Zc1/√2. When the characteristic impedance Zc1 is smaller than the reference impedance Zo, the characteristic impedance Zc2 can be set to be 1.01 times or more, 1.05 times or more, or 1.1 times or more Zc1/√2. From the viewpoint of not making the first division ratio or the second division ratio too large, Zc2 can be set to 0.3 times or more Zc1/√2, and 3 times or less Zc1/√2.

The width W1 may be 1.01 times or more, 1.4 times or more, or 1.7 times or more the width W3. Alternatively, the width W1 may be 0.99 times or less, 0.7 times or less, or 0.5 times or less the width W3. The width W2 may be 1.01 times or more, 1.1 times or more, or 10 times or less the width W3. The width W2 may be 1.01 times or more, 1.1 times or more, or 10 times or less the width W1.

As described above, the division ratio can be set to a desired value by appropriately setting the characteristic impedances Zc1 and Zc2. Even when circuits other than the distributed constant type branch line couplers are used for the divider 16 and the combiner 18, the division ratio can be set to a desired value by using a known method.

### Method of Satisfying Condition C

A method of satisfying the condition C will be described. When the Wilkinson type divider 16a illustrated in FIG. 3 is used as the divider 16, the phase difference between the signals S4 and S5 can be set to a desired value by changing the electric length of the transmission line TL17 from λ/4. Further, by making the designs of the matching circuits 22a and 22b different from each other, the phase difference between the signals S4 and S5 passing through the matching circuits 22a and 22b can be set to a desired value.

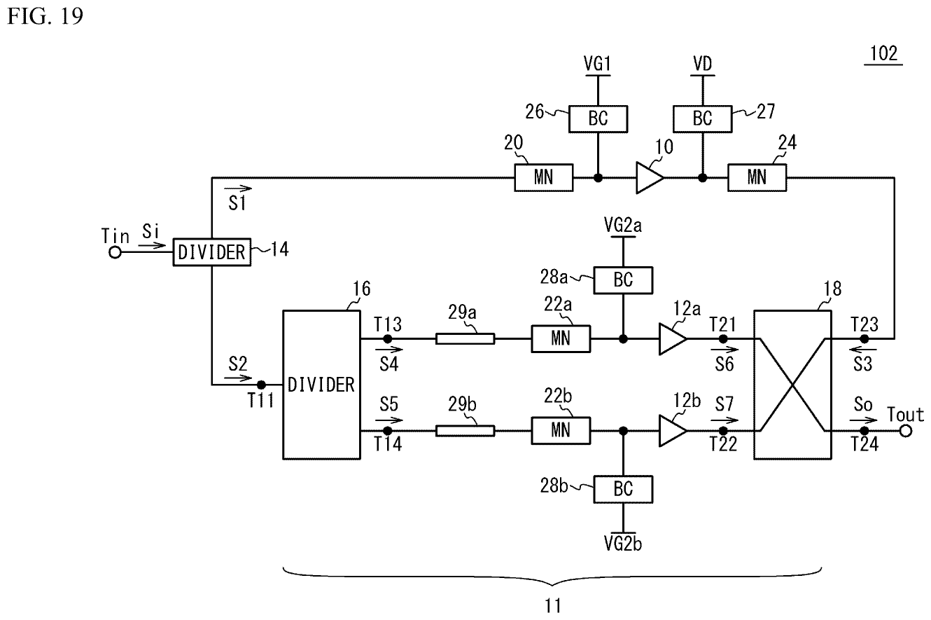

FIG. 19 is another example of the amplifier circuit according to the first embodiment. As illustrated in FIG. 19, in an amplifier circuit 102, a phase adjustment circuit 29a is provided between the divider 16 and the auxiliary amplifier 12a, and a phase adjustment circuit 29b is provided between the divider 16 and the auxiliary amplifier 12b. The phase adjustment circuits 29a and 29b are, for example, transmission lines, and the phase difference between the signals S4 and S5 can be set to a desired value by changing the electrical length. At least one of the phase adjustment circuits 29a and 29b may be provided.

The embodiments disclosed here should be considered illustrative in all respects and not restrictive. The present disclosure is not limited to the specific embodiments described above, but various variations and changes are possible within the scope of the gist of the present disclosure as described in the claims.

1. An amplifier circuit comprising:
a first divider that divides an input signal into a first signal and a second signal;
a control amplifier that amplifies the first signal and outputs an amplified signal as a third signal;
a second divider that divides the second signal into a fourth signal and a fifth signal having different phases at a center frequency of an operating band;
a first auxiliary amplifier that amplifies the fourth signal and outputs an amplified signal as a sixth signal;
a second auxiliary amplifier that amplifies the fifth signal and outputs an amplified signal as a seventh signal; and
a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, and combines the sixth signal, the seventh signal and the third signal, and outputs a combined signal as the output signal;
wherein the amplifier circuit satisfies at least one of following conditions a) to c),
a) in the combiner, a first division ratio of amplitudes of powers of signals output to the fourth end and the third end when a signal at the center frequency is input to the first end is 0.5 dB or more;
b) a second division ratio of amplitudes of powers of divided signals when a signal at the center frequency is input to the second divider is 0.5 dB or more; and
c) a phase difference between the sixth signal input to the first end and the seventh signal input to the second end at the center frequency is 85° or less or 95° or more.

2. The amplifier circuit according to claim 1, wherein
the first division ratio is 0.5 dB or more.

3. The amplifier circuit according to claim 1, wherein
the first division ratio is 2 dB or more.

4. The amplifier circuit according to claim 1, wherein
the second division ratio is 0.5 dB or more.

5. The amplifier circuit according to claim 1, wherein
the second division ratio is 3 dB or more.

6. The amplifier circuit according to claim 1, wherein
the phase difference is 85° or less or 95° or more.

7. The amplifier circuit according to claim 1, wherein
the phase difference is 0° or more and 75° or less, or 105° or more and 180° or less.

8. The amplifier circuit according to claim 1, further comprising:
a bias circuit that supplies a same bias voltage to the first auxiliary amplifier and the second auxiliary amplifier;
wherein a saturation power of the first auxiliary amplifier is equal to a saturation power of the second auxiliary amplifier.

9. The amplifier circuit according to claim 1, further comprising:
a matching circuit that matches an impedance at the center frequency viewed from the matching circuit toward the third end with an impedance at the center frequency viewed from the control amplifier toward the matching circuit;
wherein the control amplifier operates in class AB or class B, and the first auxiliary amplifier and the second auxiliary amplifier operate in class C, and
an absolute value of a first impedance at the center frequency viewed from the matching circuit toward the third end when the first auxiliary amplifier and the second auxiliary amplifier operate is 0.9 times or less or 1.1 times or more an absolute value of a second impedance at the center frequency viewed from the matching circuit toward the third end when the first auxiliary amplifier and the second auxiliary amplifier do not operate.

10. An amplifier circuit comprising:
a first divider that divides an input signal into a first signal and a second signal;
a control amplifier that operates in class AB or class B, amplifies the first signal, and outputs an amplified signal as a third signal;
a second divider that divides the second signal into a fourth signal and a fifth signal having different phases at a center frequency of an operating band;
a first auxiliary amplifier that operates in class C, amplifies the fourth signal, and outputs an amplified signal as a sixth signal;
a second auxiliary amplifier that operates in class C, amplifies the fifth signal, outputs an amplified signal as a seventh signal, and has a saturation power equal to a saturation power of the first auxiliary amplifier;
a bias circuit that supplies a same bias voltage to the first auxiliary amplifier and the second auxiliary amplifier;
a combiner that includes a first end to which the sixth signal is input, a second end to which the seventh signal is input, a third end to which the third signal is input, and a fourth end from which an output signal is output, wherein the combiner delays a phase of the sixth signal by 90° with respect to a phase of the seventh signal, combines the sixth signal, the seventh signal and the third signal, and outputs a combined signal as the output signal; and
a matching circuit that matches an impedance at the center frequency viewed from the matching circuit toward the third end with an impedance at the center frequency viewed from the control amplifier toward the matching circuit;
wherein an absolute value of a first impedance at the center frequency viewed from the matching circuit toward the third end when the first auxiliary amplifier and the second auxiliary amplifier operate is 0.9 times or less or 1.1 times or more an absolute value of a second impedance at the center frequency viewed from the matching circuit toward the third end when the first auxiliary amplifier and the second auxiliary amplifier do not operate.

11. The amplifier circuit according to claim 10, wherein
the absolute value of the first impedance is 1.5 times or more the absolute value of the second impedance.
